(19) United States
(12) Patent Application Publication
(10) Pub. No.: US 2026/0026037 A1
(43) Pub. Date: Jan. 22, 2026

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Georgios Vellianitis, Heverlee (BE); Chun-Chieh Lu, Taipei City (TW)

(73) Assignee: Taiwan Semiconductor Manufacturing Company, Ltd., Hsinchu (TW)

(21) Appl. No.: 18/786,585

(22) Filed: Jul. 29, 2024

(30) Foreign Application Priority Data
Jul. 19, 2024 (GR) 20240100505

(51) Int. Cl. H01L 29/786; H01L 29/66

(52) U.S. Cl. CPC H10D 30/6704; H10D 30/6755; H10D 99/00

(57) ABSTRACT

A semiconductor structure includes a transistor including a gate layer, source/drain contacts, a channel layer including an oxide semiconductor material, a gate dielectric layer connecting the gate layer, and a regulating layer separating the channel layer from the gate dielectric layer. The regulating layer is an oxide layer which prevents oxygen from moving through the regulating layer to the channel layer or the gate dielectric layer.

### CROSS-REFERENCE TO RELATED APPLICATION

This application claims the priority benefit of Greece application Ser. No. 20/240,100505, filed on Jul. 19, 2024. The entirety of the above-mentioned patent application is hereby incorporated by reference herein and made a part of this specification.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs. As the manufacturing technology of IC advances, fabricating transistors devices in a back end of line (BEOL) portion of the semiconductor fabrication process, instead of a front end of line (FEOL) portion of the semiconductor fabrication process, becomes an object for manufacturers. Although existing semiconductor structures have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic cross-sectional view of a semiconductor structure, in accordance with some embodiments.

FIGS. 2A-2E illustrate schematic cross-sectional views of intermediate steps during a process for forming a second semiconductor device in FIG. 1, in accordance with some embodiments.

FIGS. 3A-3D illustrate schematic cross-sectional views of variations of a second semiconductor device in FIG. 1, in accordance with some embodiments.

FIGS. 4A-4E illustrate schematic cross-sectional views of intermediate steps during a process for forming a second semiconductor device in FIG. 1, in accordance with some embodiments.

FIGS. 5A-5E illustrate schematic cross-sectional views of intermediate steps during a process for forming a second semiconductor device in FIG. 1, in accordance with some embodiments.

FIG. 6 illustrate a schematic view of a variation of a second semiconductor device in FIG. 1, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Generally, a back-end transistor (e.g., a metal-oxide-semiconductor field-effect transistor (MOSFET) or any suitable type of transistor) includes a gate layer, source/drain (S/D) contacts, and a channel layer contacting the S/D contacts. It may be beneficial to use an oxide semiconductor material (e.g., indium gallium zinc oxide (IGZO), indium zinc oxide (IZO, and/or the like) to form the channel layer as the transistor is fabricated through back-end-of-line (BEOL) processes. It is observed that the channel layer formed of the oxide semiconductor material is sensitive to hydrogen and oxygen. Since the oxide semiconductor channel has pre-existing oxygen and/or oxygen vacancies, hydrogen generated/used in the fabrication processes (e.g., a deposition of various materials) may be introduced into the oxide semiconductor channel and react with the oxide semiconductor channel, and thus the oxygen vacancies are generated in the oxide semiconductor channel. The oxygen vacancies act as a donor, and the oxide semiconductor channel may thus be doped. The oxygen and/or hydrogen concentration variations alters oxygen vacancies and doping the oxide semiconductor channel may change the electrical properties of the channel layer, lead to negative threshold voltage shift, and adversely affect a robustness of the channel layer.

Embodiments discussed herein are to provide a semiconductor structure having a back-end semiconductor device and methods for forming the same. For example, the back-end semiconductor device is a transistor in which one or more regulating layer(s) may be interposed between the channel layer and the gate dielectric layer to limit the movement of oxygen atoms to and from the channel layer. The respective regulating layer may have oxygen vacancies to store the oxygen atoms moving from the channel layer or the gate dielectric layer by reaction, and thus the regulating layer prevents oxygen from moving through the regulating layer to the channel layer or the gate dielectric layer, thereby reducing the oxygen concentration variation in the channel layer. The problems, e.g., changing the electrical properties of the channel layer, shifting threshold voltage shift, and adversely affecting the robustness of the channel layer may thus be eliminated. The reliability of the back-end semiconductor device may be improved. The back-end semiconductor device optionally includes barrier liners surrounding the source/drain electrodes to prevent hydrogen atoms from diffusing into the channel layer. Since the barrier liners may absorb or store hydrogen atoms by reaction, the channel layer separating from the S/D contacts by the barrier liners is not affected by the hydrogen diffusion, thereby reducing the hydrogen concentration variations in the channel layer. The robustness and the reliability of the back-end semiconductor device may thus be improved.

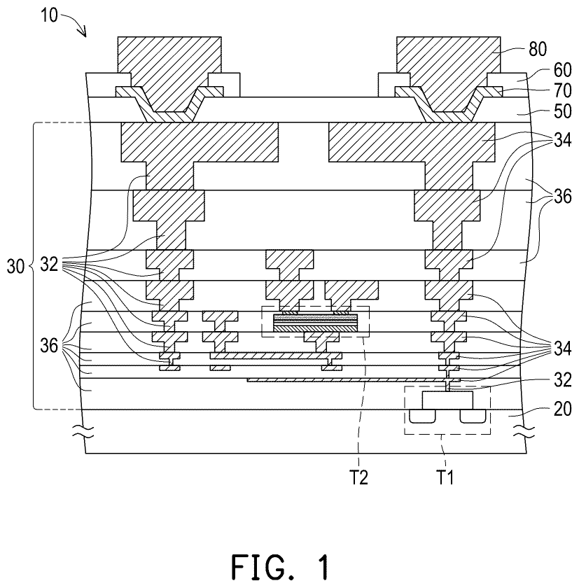

FIG. 1 illustrates a schematic cross-sectional view of a semiconductor structure, in accordance with some embodiments. Referring to FIG. 1, a semiconductor structure 10 may include a substrate 20, an interconnect structure 30, a passivation layer 50, a post-passivation layer 60, conductive pads 70, and conductive terminals 80. In some embodiments, the substrate 20 is made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The substrate 20 may be a bulk silicon substrate, a silicon-on-insulator (SOI) substrate, or a germanium-on-insulator (GOI) substrate.

In some embodiments, the substrate 20 includes various doped regions depending on circuit requirements (e.g., p-type semiconductor substrate or n-type semiconductor substrate). In some embodiments, the doped regions are doped with p-type or n-type dopants. In some embodiments, these doped regions serve as source/drain (S/D) regions of a first semiconductor device T1 formed in the substrate 20. Note that S/D region(s) may refer to a source or a drain, individually or collectively dependent upon the context. Depending on the types of the dopants in the doped regions, the first semiconductor device T1 may be referred to as an n-type transistor or a p-type transistor. In some embodiments, the first semiconductor device T1 further includes a metal gate and a channel under the metal gate. The channel is located between the source region and the drain region to serve as a path for electrons to travel when the first semiconductor device T1 is turned on. In some embodiments, the first semiconductor device T1 is formed using suitable Front-end-of-line (FEOL) process. Depending on the circuit requirements, the first semiconductor device T1 may be completely or partially embedded in the substrate 20. For simplicity, a single first semiconductor device T1 is shown in FIG. 1. However, it should be understood that more than one first semiconductor device T1 may be embedded in the substrate 20 depending on the application of the semiconductor structure 10. When multiple first semiconductor devices T1 are presented, these first semiconductor devices T1 may be separated by shallow trench isolation (STI; not shown) located between two adjacent first semiconductor devices T1. For example, the STI are also embedded in the substrate 20.

With continued reference to FIG. 1, the interconnect structure 30 is formed on the substrate 20. In some embodiments, the interconnect structure 30 includes conductive vias 32, conductive patterns 34, dielectric layers 36, and one or more second semiconductor devices T2. The conductive patterns 34 may be embedded in the dielectric layers 36. The conductive vias 32 may each penetrate through the dielectric layers 36. In some embodiments, the conductive patterns 34 located at different level heights are connected to one another through the conductive vias 32. For example, the conductive patterns 34 are electrically connected to one another through the conductive vias 32. In some embodiments, the bottommost conductive vias 32 are connected to the first semiconductor device T1 embedded in the substrate 20 and establish electrical connection between the first semiconductor device T1 and the conductive patterns 34 of the interconnect structure 30. For example, the bottommost conductive via 32 is connected to the metal gate of the first semiconductor device T1 and may be referred to as the gate contact of the first semiconductor device T1. It should be noted that in some alternative cross-sectional views, the bottommost conductive vias 32 are also connected to S/D regions of the first semiconductor device T1 and may be referred to as the S/D contacts of the first semiconductor device T1.

In some embodiments, a material of the dielectric layers 36 includes oxide (e.g., SiO₂ or the like), a nitride (e.g., SiN or the like), an oxynitride (e.g., SiON or the like), other high-k dielectrics, combinations thereof, and/or the like. In other embodiments, the dielectric layers 36 include polyimide, epoxy resin, acrylic resin, phenol resin, benzocyclobutene (BCB), polybenzooxazole (PBO), or any other suitable polymer-based dielectric material. The dielectric layers 36 may be formed by suitable fabrication techniques such as spin-on coating, chemical vapor deposition (CVD), plasma-enhanced chemical vapor deposition (PECVD), or the like. Material(s) of the conductive patterns 34 and the conductive vias 32 may include Al, Ti, Cu, Ni, W, alloys thereof, combinations thereof, or the like. The conductive patterns 34 and the conductive vias 32 may be formed by electroplating, deposition, lithography and etching, and/or any suitable process. In some embodiments, the conductive patterns 34 and the underlying conductive vias 32 are formed simultaneously through a dual damascene process. It should be noted that the number of the dielectric layers 36, the number of the conductive patterns 34, and the number of the conductive vias 32 illustrated in FIG. 1 are merely for illustrative purposes, and the disclosure is not limited thereto. Fewer or more layers of the dielectric layers 36, the conductive patterns 34, and/or the conductive vias 32 may be formed depending on the circuit design.

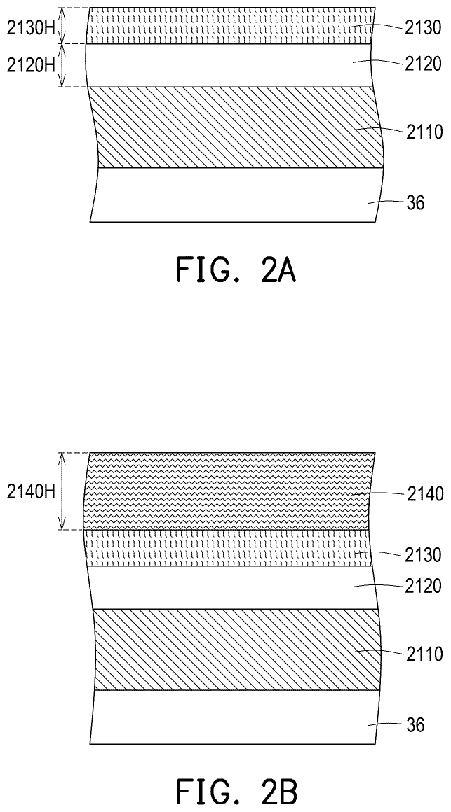

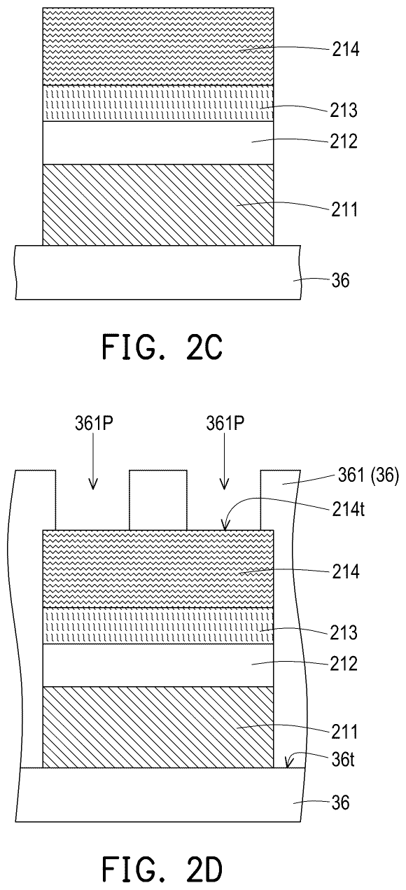

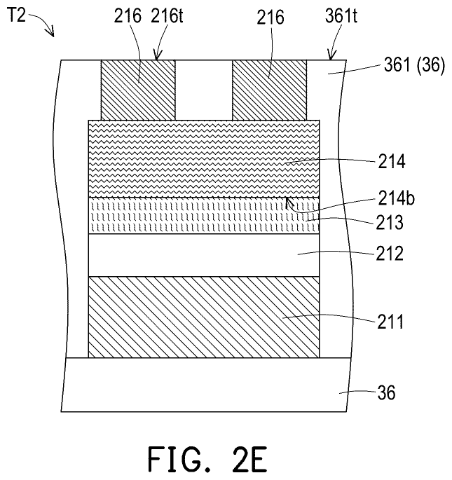

With continued reference to FIG. 1, the second semiconductor devices T2 may be embedded in one or more dielectric layers 36 of the interconnect structure 30. In some embodiments, the second semiconductor device T2 is formed using suitable BEOL process. The formation method and the detailed structure of the second semiconductor devices T2 will be described in detail later in accompanying with FIGS. 2A-2E. In some embodiments, the passivation layer 50, the conductive pads 70, the post-passivation layer 60, and the conductive terminals 80 are sequentially formed on the interconnect structure 30. In some embodiments, the passivation layer 50 is disposed on the topmost dielectric layer 36 and the topmost conductive patterns 34. In some embodiments, the passivation layer 50 has openings partially exposing the topmost conductive pattern 34. The passivation layer 50 may be or include silicon oxide, silicon nitride, silicon oxy-nitride, or any suitable dielectric materials, and may be formed by suitable fabrication techniques such as HDP-CVD, PECVD, or the like.

With continued reference to FIG. 1, the conductive pads 70 may be formed over the passivation layer 50. In some embodiments, the conductive pads 70 extend into the openings of the passivation layer 50 to be in direct contact with the topmost conductive patterns 34. The conductive pads 70 may be electrically connected to the interconnect structure 30. In some embodiments, the conductive pads 70 include aluminum pads, copper pads, titanium pads, or other suitable metal pads. The conductive pads 70 may be formed by electroplating, deposition, lithography and etching, and/or any suitable process. It should be noted that the number and the shape of the conductive pads 70 illustrated herein are merely for illustrative purposes, and the disclosure is not limited thereto. The number and the shape of the conductive pad 70 may be adjusted based on demand. In some embodiments, the post-passivation layer 60 is formed over the passivation layer 50 and the conductive pads 70. The post-passivation layer 60 may be formed on the conductive pads 70 to protect the conductive pads 70. In some embodiments, the post-passivation layer 60 has contact openings partially exposing the conductive pads 70. The post-passivation layer 60 may be or include polyimide, PBO, BCB, or any suitable polymer, and may be formed by suitable fabrication techniques such as HDP-CVD, PECVD, or the like.

The conductive terminals 80 may be formed over the post-passivation layer 60 and the conductive pads 70. In some embodiments, the conductive terminals 80 extend into the contact openings of the post-passivation layer 60 to be in direct contact with the corresponding conductive pad 70. The conductive terminals 80 may be electrically connected to the interconnect structure 30 through the conductive pads 70. In some embodiments, the conductive terminals 80 are conductive pillars, conductive posts, conductive balls, conductive bumps, or the like. In some embodiments, a material of the conductive terminals 80 includes a variety of metals, metal alloys, or metals and mixture of other materials. For example, the conductive terminals 80 may be made of Al, Ti, Cu, Ni, W, Sn, and/or alloys thereof. The conductive terminals 80 are formed by deposition, electroplating, screen printing, or any suitable methods. In some embodiments, the conductive terminals 80 are used to establish electrical connection with other components (not shown) subsequently formed or provided.

It should be noted that FIG. 1 is provided for illustrative purposes only, and the semiconductor structure 10 may utilize fewer or additional elements according to some embodiments. One or more packaging/semiconductor process may be performed on the semiconductor structure 10 depending on product requirements. The advanced packaging technologies enable production of semiconductor structure 10 with enhanced functionalities. The embodiments described herein are not intended to be limited to the embodiments described, and the embodiments may be implemented in any suitable methods and structures (e.g., integrated fanout packages, package-on-package, chip-on-wafer-on-substrate packages, system-on-integrated-circuit structure, etc.). All such embodiments are fully intended to be included within the scope of the embodiments.

FIGS. 2A-2E illustrate schematic cross-sectional views of intermediate steps during a process for forming the second semiconductor device T2 in FIG. 1, in accordance with some embodiments. For simplicity, portions of the semiconductor structure below the second semiconductor device T2 are omitted in FIGS. 2A-2E. It is understood that additional operations may be provided before, during, and after processes shown by FIGS. 2A-2E, and some of the operations described below may be replaced or eliminated, for additional embodiments of the method. The order of the operations/processes may be interchangeable. The second semiconductor device depicted in the following paragraphs may be used as the second semiconductor device in FIG. 1. Like reference numerals denote like features with similar structures and compositions.

Referring to FIG. 2A and with reference to FIG. 1, a gate material layer 2110 may be formed on one of the dielectric layers 36. In some embodiments, the gate material layer 2110 is formed on the top surfaces of the dielectric layer 36 and the conductive pattern 34 (not shown in FIG. 2A but can refer to FIG. 1) covered by the dielectric layer 36, where the gate material layer 2110 is in physical and electrical contact with the conductive pattern 34. In alternative embodiments, the gate material layer 2110 is formed on top surfaces of the dielectric layer 36 and the conductive via 36 (not shown in FIG. 2A but can refer to FIG. 1) covered by the dielectric layer 36, where the gate material layer 2110 is in physical and electrical contact with the conductive via 32. The gate material layer 2110 may include a metallic material, a metal compound, polycrystalline silicon, doped silicon, combinations thereof, or other suitable gate material(s). For example, the gate material layer 2110 includes Ti, W, Ni, Cu, Al, Ag, nitride thereof (e.g., TaN, TiN, or the like), metal silicide, metal alloys, combinations thereof, and/or the like. The gate material layer 2110 may be formed on the dielectric layer 36 through any suitable deposition processes such as CVD, PVD, and/or the like.

With continued reference to FIG. 2A, a gate dielectric material layer 2120 may be formed on the gate material layer 2110. The gate dielectric material layer 2120 may be a single layer or may be a composite layer formed of different materials. For example, the gate dielectric material layer 2120 includes, but not limited to, HfO₂, Al₂O₃, HfZrOₓ, MgO, HfO₂—Al₂O₃ alloy, combinations thereof, or suitable gate dielectric materials. The gate dielectric material layer 2120 may be formed by CVD, PVD ALD, PEALD, or any suitable deposition process. In some embodiments, the gate dielectric material layer 2120 is formed with a thickness 2120H ranging from about 5 nm to about 20 nm. It is realized that the thickness range is an example and may be changed to other suitable values depending on product requirements.

Still referring to FIG. 2A, a regulating material layer 2130 may be formed on the gate dielectric material layer 2120. The regulating material layer 2130 may be a single layer or may be a composite layer formed of different materials, and may be deposited through ALD, CVD, PVD, or any suitable deposition process. The regulating material layer 2130 and the gate dielectric material layer 2120 may be formed of different materials, and a visible interface may be formed therebetween. In some embodiments, the regulating material layer 2130 is thinner than the gate dielectric material layer 2120. For example, the regulating material layer 2130 is formed with a thickness 2130H ranging from about 0.1 nm to about 3 nm. In some embodiments, a ratio of the thickness 2120H to the thickness 2130H ranges from about 1.7 to about 200, such as about 5 to about 150. It is realized that the thickness range is an example and may be changed to other suitable values depending on product requirements.

In some embodiments, the regulating material layer 2130 is of the form AₓO_{y}, where A represents metallic cations (e.g., Nb, Ta, Ti, W, V, Cr, Fe, La, V, Al, etc.) or non-metallic cations (e.g., P or the like), x represents the number of the cations (A) or atoms, O represents oxygen anions (O) or atoms, and y represents the number of the oxygen anions (O) or atoms. The regulating material layer 2130 may act as an oxygen reservoir in the resulting device. For example, the regulating material layer 2130 has a high oxidation state (e.g., +2, +3, +4, +5, or greater than +5 such as +9). In some embodiments, in the generic form AₓO_{y} of the regulating material layer 2130, y is greater than x. The oxidation state of the regulating material layer 2130 may be determined by the equation: x*(the oxidation state of A)+y*(the oxidation state of oxygen)=0, where the oxidation state of oxygen is −2. The average oxidation state of the regulating material layer 2130 may range between +3 and +5, or higher than +5 (such as +9, if possible). The regulating material layer 2130 may have 3 to 5 (or even to 9, if possible) valence bonds. In some embodiments, the regulating material layer 2130 includes, but not limited to, pentoxides (e.g., Nb₂O₅, Ta₂O₅, Ti₃O₅, W₂O₅, V₂O₅, P₂O₅, etc.), trioxides (e.g., Cr₂O₃, Fe₂O₃, La₂O₃, V₂O₃, Al₂O₃, etc.), a combination thereof, etc. In some embodiments, the regulating material layer 2130 is referred to as a dielectric osmotic layer.

Referring to FIG. 2B with reference to FIG. 2A, a channel material layer 2140 may be formed on the regulating material layer 2130. The channel material layer 2140 may be a single layer or may be a composite layer formed of different materials. In some embodiments, the channel material layer 2140 is formed of one or more oxide semiconductor material(s). For example, the channel material layer 2140 includes, but not limited to, IGZO, IZO, InOₓ, InWOₓ, MgZnAlOₓ, ZnOₓ, SnOₓ, NiOₓ, Cu₂O, CuCrOₓ, metal oxides, combinations thereof, or any suitable channel material(s). The channel material layer 2140 may be formed by CVD, PVD ALD, PECVD, or any suitable deposition process. In some embodiments, the channel material layer 2140 is formed with a thickness 2140H ranging from about 1 nm to about 20 nm. It is realized that the thickness range is an example and may be changed to other suitable values depending on product requirements.

Referring to FIG. 2C with reference to FIG. 2B, a patterning process may be performed to pattern a stack of the channel material layer 2140, the regulating material layer 2130, the gate dielectric material layer 2120, and the gate material layer 2110 to respectively form a channel layer 214, a regulating layer 213 underlying the channel layer 214, a gate dielectric layer 212 underlying the regulating layer 213, and a gate layer 211 underlying the gate dielectric layer 212. For example, the patterning process includes one or more lithography and etching, or any suitable patterning method. In some embodiments, a patterned photoresist (not shown) is formed over the channel material layer 2140 to act as an etch mask, portions of the channel material layer 2140, the regulating material layer 2130, the gate dielectric material layer 2120, and the gate material layer 2110 that are not covered by the patterned photoresist may be removed during the etching, and the remaining portions of the channel material layer 2140, the regulating material layer 2130, the gate dielectric material layer 2120, and the gate material layer 2110 form the channel layer 214, the regulating layer 213, the gate dielectric layer 212, and the gate layer 211, respectively. The patterned photoresist may then be removed through any suitable removal process including stripping, ashing, or the like. In some embodiments, the sidewalls of the stacked layers (e.g., the channel layer 214, the regulating layer 213, the gate dielectric layer 212, and the gate layer 211) are substantially aligned (e.g., coplanar) with one another, within process variations. The sidewalls of the stacked layers may be substantially vertical or may be slanted, depending on process and product requirements.

Referring to FIG. 2D with reference to FIG. 2C, a dielectric layer 361 with contact openings 361P may be formed on the top surface 36t of the dielectric layer 36 to cover the stack of the channel layer 214, the regulating layer 213, the gate dielectric layer 212, and the gate layer 211. The dielectric layer 361 may extend along the sidewalls of the channel layer 214, the regulating layer 213, the gate dielectric layer 212, and the gate layer 211. The dielectric layer 361 may be a part of the dielectric layers 36 described in FIG. 1, and thus the material and the forming method of the dielectric layer 361 is not repeated herein. The contact openings 361P of the dielectric layer 361 may be formed to expose at least a portion of the channel layer 214. In some embodiments, the contact openings 361P expose portions of the top surface 214t of the channel layer 214. For example, the contact openings 361P are formed through one or more lithographic and etching processes or any suitable removal process. In some embodiments, a patterned photoresist (not shown) is formed on the dielectric layer 361 to be used as an etch mask so that portions of the dielectric layer 361 uncovered by the patterned photoresist are removed during the etching process, and the patterned photoresist is then removed thorough a stripping process or ashing process. The depth of the respective contact opening 361P may vary depending on product and process requirements.

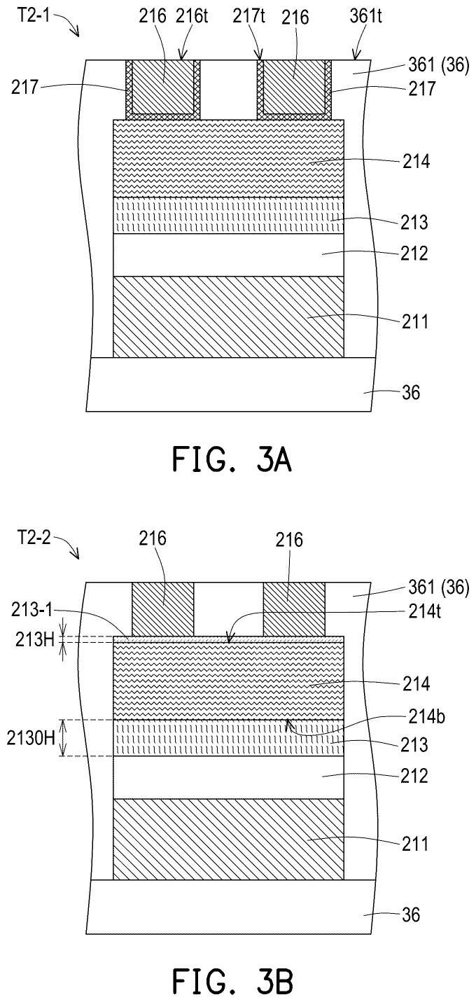

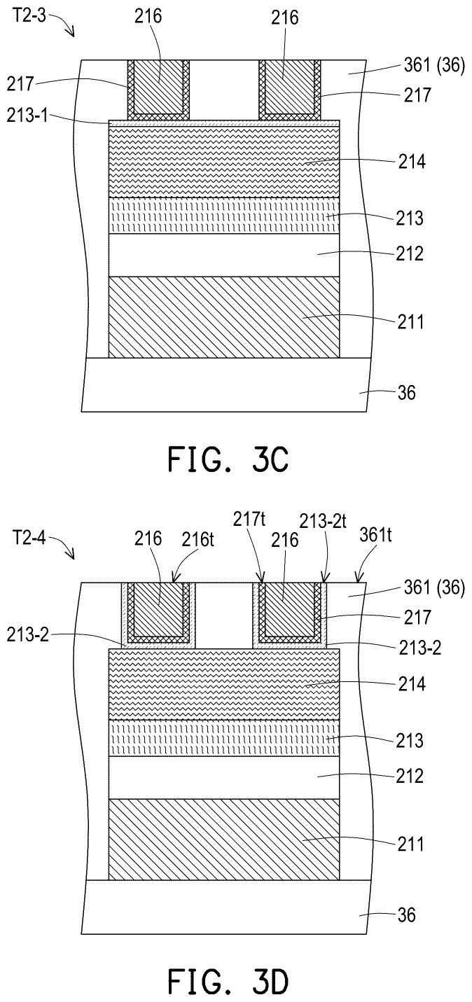

Referring to FIG. 2E with reference to FIG. 2D, S/D contacts 216 may be formed in the contact openings 361P of the dielectric layer 361. For example, the S/D contacts 216 are in direct contact with the top surface 214t of the channel layer 214. In some embodiments, the S/D contacts 216 are formed by depositing one or more conductive material(s) to fill up the contact openings 361P using CVD, ALD, PVD, plating, or any suitable deposition techniques. The material(s) of the respective S/D contact 216 may include, but not limited to, Co, W, Cu, Ti, Ta, Al, Zr, Hf, combinations thereof, alloys thereof, etc. In some embodiments, a planarization process (e.g., chemical mechanical polishing (CMP), grinding, etching, a combination thereof, etc.) is performed on the S/D contacts 216 and the dielectric layer 361. For example, top surfaces (216t and 361t) of the S/D contacts 216 and the dielectric layer 361 are substantially leveled (or coplanar), within process variations. In some embodiments, the dielectric layer 361 laterally surrounds the respective S/D contact 216 and may be in direct contact with the sidewalls of the S/D contacts 216. In alternative embodiments, the respective S/D contact 216 are separated from the dielectric layer 361 and the channel layer 214 through liner(s) as will be described later in accompanying with FIGS. 3A-3D.

Up to here, the second semiconductor device T2 in the semiconductor structure 10 is obtained. The second semiconductor device T2 may include a stacked structure including the gate layer 211, the gate dielectric layer 212, the regulating layer 213, and the channel layer 214 sequentially stacked from the bottom to the top, and the S/D contacts 216 located on the stacked structure. The S/D contacts 216 may be further electrically coupled to the conductive patterns 34 and/or the conductive vias 32 of the interconnection structure 30 (shown in FIG. 1). In alternative embodiments, additional features may be added in the semiconductor structure shown in FIGS. 2E and 1, and some features in the semiconductor structure shown in FIGS. 2E and 1 may be modified, replaced, or eliminated without departure of the spirit and scope of the present disclosure.

With continued reference to FIG. 2E, the regulating layer 213 may separate the channel layer 214 from the gate dielectric layer 212 in the thickness direction of the second semiconductor device T2. In some embodiments, the regulating layer 213 covers the entirety of the bottom surface 214b of the channel layer 214. Alternatively, the regulating layer 213 covers a major portion of the bottom surface 214b of the channel layer 214. The regulating layer 213 is an oxide layer and may have a high oxidation state to act as an oxygen reservoir in the second semiconductor device T2. When fabricating the second semiconductor device T2 (e.g., the deposition process of various layers), the oxygen atoms/ions in the channel layer 214 may move upward to the S/D contacts 216 and downward to the regulating layer 213. During the operation of the second semiconductor device T2, the oxygen atoms/ions in the channel layer 214 may move toward the regulating layer 213. Similarly, the oxygen atoms/ions in the gate dielectric layer 212 may tend to move toward the regulating layer 213. During the operation and/or fabrication of the second semiconductor device T2, the regulating layer 213 may have oxygen vacancies (e.g., oxide bond locations where the oxygen has been removed) which may be filled with oxygen atoms/ions due to the oxygen movement from the channel layer 214 and/or the oxygen movement from the gate dielectric layer 212. The regulating layer 213 having oxygen vacancies may act as oxygen capture region. For example, the regulating layer 213 is used to regulate or limit the oxygen movement toward/from the channel layer 214. The oxygen movement from channel layer 214 toward the gate dielectric layer 212 and the oxygen movement from the gate dielectric layer 212 toward the channel layer 214 may be prevented by interposing the regulating layer 213 between the channel layer 214 and the gate dielectric layer 212. The oxygen concentration variations during device operation and fabrication may thus be reduced, and the undesirable shift of the threshold voltage of the second semiconductor device T2 may be avoided. The reliability and electrical performance of the second semiconductor device T2 may be improved.

FIGS. 3A-3D illustrate schematic cross-sectional views of variations of a second semiconductor device in FIG. 1, in accordance with some embodiments. Unless explicitly stated otherwise, the materials and the formation methods of the components in these embodiments are essentially the same as the like components, which are denoted by like reference numerals in the embodiments described in accompanying with FIGS. 2A-2E.

Referring to FIG. 3A and with reference to FIG. 2E, the second semiconductor device T2-1 in FIG. 3A is similar to the second semiconductor device T2 shown in FIG. 2E, except that the second semiconductor device T2-1 further includes barrier liners 217 respectively surrounding the S/D contacts 216. For example, after forming the contact openings 361P of the dielectric layer 361 (see FIG. 2D) and before forming the S/D contacts 216 (see FIG. 2E), a layer of barrier material (not shown) is conformally formed on the dielectric layer 316 and in the contact openings 361P to cover the top surface and the inner sidewalls of the dielectric layer 316 and the top surface 214t of the channel layer 214 exposed by the contact openings 361P. Next, the material(s) of the S/D contacts 216 may be formed on the barrier material, and then excess portions of the barrier material and the S/D contacts 216 may be removed from the top surface 361t of the dielectric layer 361 so as to form the barrier liners 217 lining the contact openings 361P and the S/D contacts 216 on the barrier liners 217 and filling the contact openings 361P. In some embodiments, a planarization process is performed such that the top surfaces (216t and 361t) of the S/D contacts 216 and the dielectric layer 361 may be substantially leveled (or coplanar) with the top surfaces 217t of the barrier liners 217, within process variations.

With continued reference to FIG. 3A, the respective barrier liner 217 may separate the overlying S/D contact 216 from the channel layer 214 in the thickness direction of the second semiconductor device T2-1 and may laterally separate the overlying S/D contact 216 from the dielectric layer 361. The barrier liners 217 may include any suitable hydrogen barrier material. For example, the barrier liners 217 separating the S/D contacts 216 from the channel layer 214 are configured to prevent hydrogen atoms from diffusing through the barrier liners 217. The hydrogen atoms moving away from the S/D contacts 216 may be absorbed (or stored) by the barrier liners 217. In this manner, the hydrogen movement may be limited by the barrier liners 217 and does not reach the channel layer 214. Therefore, the hydrogen diffusion phenomenon and associated adverse effects on the second semiconductor device T2-1 may be reduced. The robustness and the reliability of the second semiconductor device T2-1 may thus be improved.

Referring to FIG. 3B and with reference to FIG. 2E, the second semiconductor device T2-2 in FIG. 3B is similar to the second semiconductor device T2 shown in FIG. 2E, except that the second semiconductor device T2-2 further includes a regulating layer 213-1 disposed between the channel layer 214 and the S/D contacts 216. In some embodiments, the regulating layer 213-1 has the conduction band minimum substantially aligned with the valence band maximum such that the contact resistance between the channel layer 214 and the S/D contacts 216 does not degrade by the regulating layer 213-1. In some embodiments, the regulating layer 213-1 has a thickness 213H less than the thickness 2130H of the regulating layer 213. The thickness 213H of the regulating layer 213-1 may be designed to allow the contact resistance to be in acceptable and workable ranges while maintaining the ability of regulating the oxygen movement from/to the channel layer 214. For example, the regulating layers (213 and 213-1) are disposed at two opposing surfaces of the channel layer 214. In some embodiments, the regulating layer 213 fully or partially covers the bottom surface 214b of the channel layer 214, and the regulating layer 213-1 fully or partially covers the top surface 214t of the channel layer 214. The S/D contacts 216 may be separated from the channel layer 214 by the regulating layer 213-1, and the gate dielectric layer 212 may be separated from the channel layer 214 by the regulating layer 213. In this manner, the oxygen atoms moving away from the channel layer 214 may be stopped at the regulating layers (213 and 213-1). The robustness and the reliability of the second semiconductor device T2-2 may thus be improved.

Referring to FIG. 3C and with reference to FIG. 3B and FIG. 3A, the second semiconductor device T2-3 in FIG. 3C is similar to the second semiconductor device T2-2 shown in FIG. 3B, except that the second semiconductor device T2-3 further includes the barrier liners 217 lining the sidewalls and the bottom surfaces of the S/D contacts 216. The material and the forming method of the barrier liners 217 are similar to those of the barrier liners 217 described in FIG. 3A, and thus the details thereof are not repeated for the sake of brevity. In some embodiments, the bottom portions of the barrier liners 217 are in direct contact with the regulating layer 213-1. The thicknesses of the barrier liners 217 and the regulating layer 213-1 may be designed to allow the contact resistance to be in acceptable and workable ranges while maintaining the ability of regulating the oxygen and hydrogen movement from/to the channel layer 214. By configuring the barrier liners 217 and the regulating layer 213-1, the robustness and the reliability of the second semiconductor device T2-3 may be improved.

Referring to FIG. 3D and with reference to FIG. 3C, the second semiconductor device T2-4 in FIG. 3D is similar to the second semiconductor device T2-3 shown in FIG. 3C, except that regulating layers 213-2 of the second semiconductor device T2-4 are conformally formed in the contact openings 361P (labeled in FIG. 2D) of the dielectric layer 361. For example, before forming the barrier liners 217 as described in FIG. 3A, a layer of regulating material is conformally formed on the top surface and the inner sidewalls of the dielectric layer 361 and also on the top surface of the channel layer 214. Next, the barrier material may be conformally formed on the regulating material, and then the material(s) of the S/D contacts 216 may be formed to fill the rest area of the contact openings 361P. Excess portions of the regulating material, the barrier material, and the materials of the S/D contacts 216 may be removed from the top surface 361t of the dielectric layer 361. For example, a planarization process is performed such that the top surfaces (216t and 361t) of the S/D contacts 216 and the dielectric layer 361 may be substantially leveled (or coplanar) with the top surfaces 217t of the barrier liners 217 and the top surfaces 213-2t of the regulating layers 213-2, within process variations. The respective regulating layer 213-2 may separate the overlying barrier liner 217 from the channel layer 214 in the thickness direction of the second semiconductor device T2-4 and may laterally separate the overlying barrier liner 217 from the dielectric layer 361. By configuring the barrier liners 217 and the regulating layer 213-2, the robustness and the reliability of the second semiconductor device T2-4 may be improved.

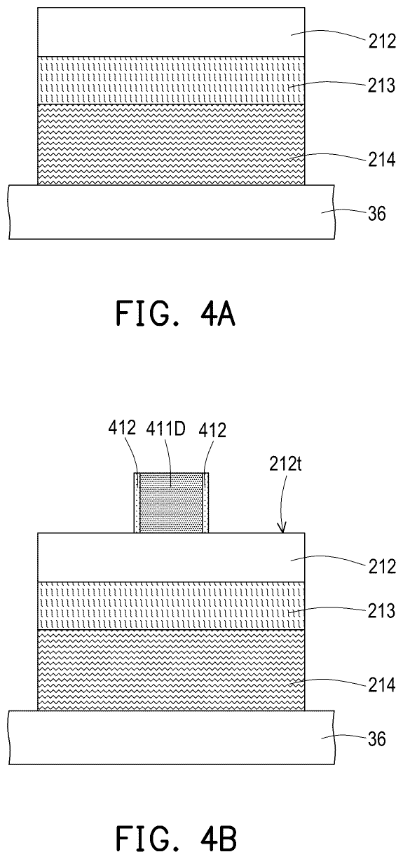

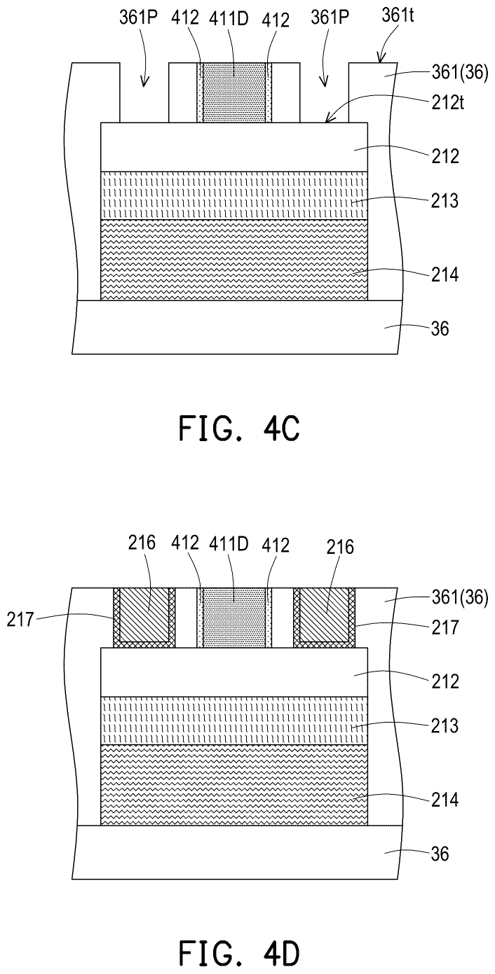

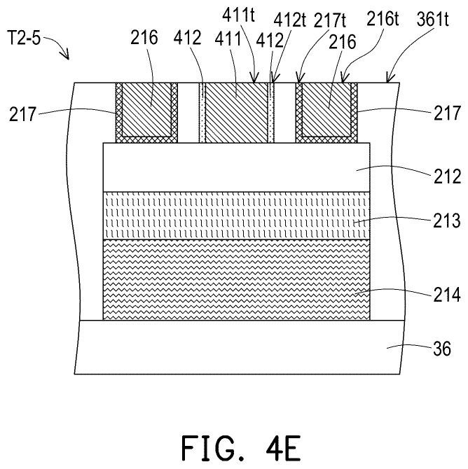

FIGS. 4A-4E illustrate schematic cross-sectional views of intermediate steps during a process for forming a second semiconductor device in FIG. 1, in accordance with some embodiments. Unless explicitly stated otherwise, the materials and the formation methods of the components in these embodiments are essentially the same as the like components, which are denoted by like reference numerals in the embodiments described in accompanying with FIGS. 2A-2E.

Referring to FIG. 4A and with reference to FIGS. 2A-2C, a stack of the channel layer 214, the regulating layer 213, and the gate dielectric layer 212 may be formed on the dielectric layer 36. The materials of the channel layer 214, the regulating layer 213, and the gate dielectric layer 212 are similar to the channel material layer 2140, the regulating material layer 2130, and the gate dielectric material layer 2120 described in FIGS. 2A-2B. For example, the channel material layer, the regulating material layer, and the gate dielectric material layer are sequentially formed on the dielectric layer 36, and then a patterning process is performed to remove portions of the channel material layer, the regulating material layer, and the gate dielectric material layer so as to respectively form the channel layer 214, the regulating layer 213, and the gate dielectric layer 212.

Referring to FIG. 4B and with reference to FIG. 4A, a dummy gate 411D may be formed on the gate dielectric layer 212, and sidewall spacers 412 may be formed on the sidewalls of the dummy gate 411D. For example, a layer of dummy gate material (e.g., poly-silicon with or without being doped or other suitable dummy gate material(s)) is formed on the top surface 212t of the gate dielectric layer 212 through CVD, PVD or the like, and then a patterning process is performed on the dummy gate material to form the dummy gate 411D on the gate dielectric layer 212. Next, a spacer material (e.g., silicon oxide, silicon nitride or other suitable spacer material(s)) may be conformally formed on the dummy gate 411D and the gate dielectric layer 212, and then excess portions of the spacer material may be removed through etching or other suitable removal process to form the sidewall spacers 412 covering the sidewalls of the dummy gate 411D.

Referring to FIG. 4C and with reference to FIG. 4B and FIG. 2C, the dielectric layer 361 with the contact openings 361P may be formed on the top surface 36t of the dielectric layer 36 to cover the structure including the channel layer 214, the regulating layer 213, and the gate dielectric layer 212, the dummy gate 411D, and the sidewall spacers 412. The contact openings 361P may accessibly expose at least a portion of the top surface 212t of the gate dielectric layer 212. The dielectric layer 361 and the contact openings 361P may be similar to the dielectric layer 361 and the contact openings 361P described in FIG. 2C, and thus the details thereof are not repeated herein.

Referring to FIG. 4D and with reference to FIG. 4C, FIG. 2E, and FIG. 3A, the S/D contacts 216 may be formed in the contact openings 361P. The material and the forming method of the S/D contacts 216 may be similar to those of the S/D contacts 216 described in FIG. 2E. In some embodiments, the barrier liners 217 are formed in the contact openings 361P to separate the S/D contacts 216 from the gate dielectric layer 212. The material and the forming method of the barrier liners 217 may be similar to those of the barrier liners 217 described in FIG. 3A. It is appreciated that the formation of the barrier liners 217 is optional, and in some embodiments, the barrier liners 217 are omitted. In such embodiment, the S/D contacts 216 formed in the contact openings 361P are in direct contact with the top surface 212t of the gate dielectric layer 212 and the inner sidewalls of the dielectric layer 361.

Referring to FIG. 4E and with reference to FIG. 4D, the dummy gate 411D may be replaced with the gate layer 411. For example, an etching process or other suitable removal process may be performed to selectively remove the dummy gate 411D. One or more gate material(s) may then be formed in the opening where the dummy gate 411D was formed so as to form the gate layer 411 laterally surrounded by the sidewall spacers 412. The material of the gate layer 411 may be similar to the gate material layer 2110 described in FIG. 2A. In some embodiments, a planarization process is performed on the dielectric layer 361 such that the top surface 361t of the dielectric layer 361 may be substantially leveled (or coplanar) with the top surfaces (411t and 412t) of the gate layer 411 and the sidewall spacers 412, the top surfaces 216t of the S/D contacts 216, and the top surfaces 217t of the barrier liners 217 (if exist), within process variations.

Up to here, the second semiconductor device T2-5 is obtained. The second semiconductor device T2-5 may include a stacked structure including the channel layer 214, the regulating layer 213, and the gate dielectric layer 212 sequentially stacked from the bottom to the top, and the S/D contacts 216 and the gate layer 411 located on the stacked structure. The S/D contacts 216 may be disposed on a side of the gate dielectric layer 212 on which the gate layer 411 is disposed, and the pair of S/D contacts 216 may be disposed at two opposing sidewalls of the gate layer 411. The second semiconductor device T2-5 may be formed in the interconnect structure 30 (shown in FIG. 1). For example, the S/D contacts 216 and the gate layer 411 are further electrically coupled to the conductive patterns 34 and/or the conductive vias 32 of the interconnect structure 30 (shown in FIG. 1). In some embodiments, the second semiconductor device T2-5 is referred to as a front-gated transistor structure. In alternative embodiments, additional features may be added in the semiconductor structure shown in FIG. 4E, and some features in the semiconductor structure shown in FIG. 4E may be modified, replaced, or eliminated without departure of the spirit and scope of the present disclosure.

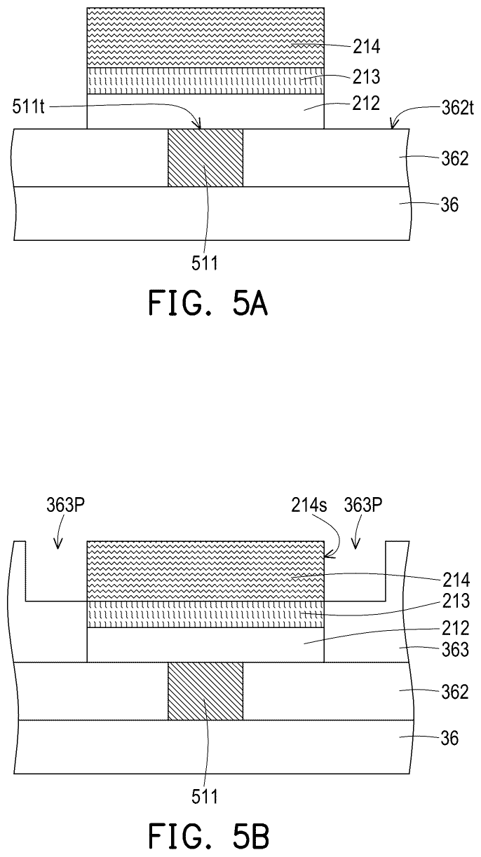

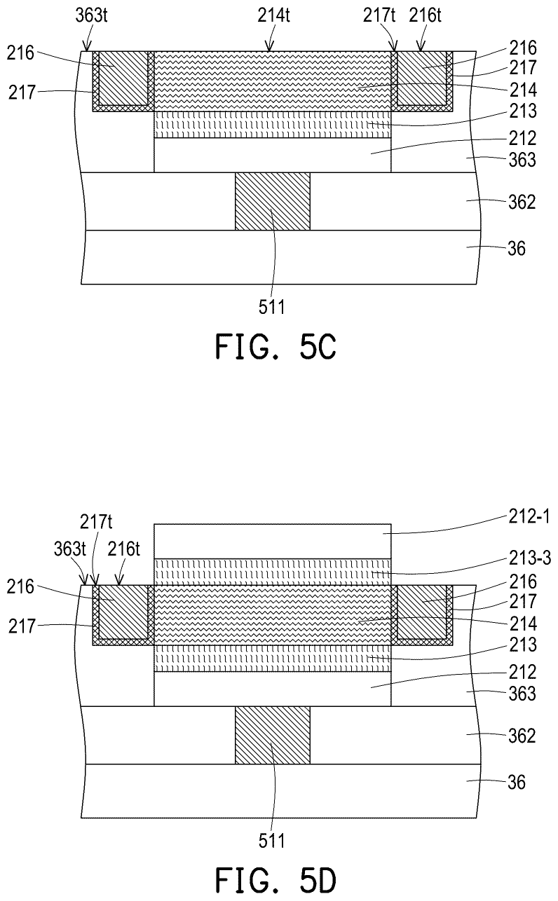

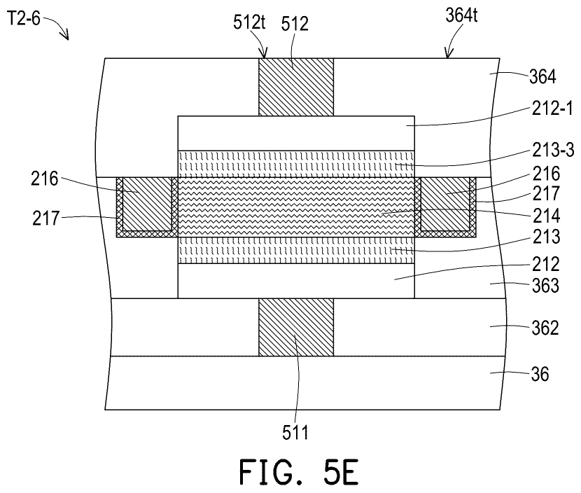

FIGS. 5A-5E illustrate schematic cross-sectional views of intermediate steps during a process for forming a second semiconductor device in FIG. 1, in accordance with some embodiments. Unless explicitly stated otherwise, the materials and the formation methods of the components in these embodiments are essentially the same as the like components, which are denoted by like reference numerals in the embodiments described in accompanying with FIGS. 2A-2E.

Referring to FIG. 5A and with reference to FIGS. 2A-2C, a first gate layer 511 is formed in the dielectric layer 362 over the dielectric layer 36. In some embodiments, the first gate layer 511 is laterally covered by the dielectric layer 362. The top surfaces (511t and 362t) of the first gate layer 511 and the dielectric layer 362 may be substantially leveled (or coplanar), within process variations. The material of the first gate layer 511 may be similar to the gate material layer 2110 described in FIG. 2A. The dielectric layer 362 may be a part of the dielectric layers 36 described in FIG. 1, and thus the material and the forming method of the dielectric layer 361 is not repeated herein. In some embodiments, the first gate layer 511 is formed on the top surfaces of the dielectric layer 36 and the conductive pattern 34 (not shown in FIG. 5A but can refer to FIG. 1) covered by the dielectric layer 36, where the first gate layer 511 is in physical and electrical contact with the conductive pattern 34. In alternative embodiments, the first gate layer 511 is formed on top surfaces of the dielectric layer 36 and the conductive via 36 (not shown in FIG. 5A but can refer to FIG. 1) covered by the dielectric layer 36, where the first gate layer 511 is in physical and electrical contact with the conductive via 32.

With continued reference to FIG. 5A, a stack of the gate dielectric layer 212, the regulating layer 213, and the channel layer 214 may be formed on the first gate layer 511 and the dielectric layer 362. The materials of the gate dielectric layer 212, the regulating layer 213, and the channel layer 214 are similar to the gate dielectric material layer 2120, the regulating material layer 2130, and the channel material layer 2140 described in FIGS. 2A-2B. For example, the gate dielectric material layer, the regulating material layer, and the channel material layer are sequentially formed on the top surfaces (511t and 362t) of the first gate layer 511 and the dielectric layer 362, and then a patterning process is performed to remove portions of the gate dielectric material layer, the regulating material layer, and the channel material layer so as to respectively form the gate dielectric layer 212, the regulating layer 213, and the channel layer 214.

Referring to FIG. 5B and with reference to FIG. 5A, a dielectric layer 363 may be formed on the dielectric layer 362 to cover the stack of the gate dielectric layer 212, the regulating layer 213, and the channel layer 214. The dielectric layer 363 may be a part of the dielectric layers 36 described in FIG. 1, and thus the material and the forming method of the dielectric layer 361 is not repeated herein. In some embodiments, the dielectric layer 363 is formed with contact openings 363P which accessibly expose at least the sidewalls 214s of the channel layer 214. The sidewalls of the regulating layer 213 may remain covered by the dielectric layer 363. For example, the depth of the contact opening 363P is substantially equal to the thickness of the channel layer 214. However, the depths of the contact openings 363P may be adjusted depending on process and product requirements.

Referring to FIG. 5C and with reference to FIG. 5B, the S/D contacts 216 may be formed in the contact openings 363P of the dielectric layer 363. The material and the forming method of the S/D contacts 216 may be similar to those of the S/D contacts 216 described in FIG. 2E. In some embodiments, the barrier liners 217 are formed in the contact openings 363P to separate the S/D contacts 216 from the sidewalls 214s of the channel layer 214. The material and the forming method of the barrier liners 217 may be similar to those of the barrier liners 217 described in FIG. 3A. It is appreciated that the formation of the barrier liners 217 is optional, and in some embodiments, the barrier liners 217 are omitted. For example, the S/D contacts 216 formed in the contact openings 363P are in direct contact with the sidewalls 214s of the channel layer 214 and the inner surfaces of the dielectric layer 363. In some embodiments, a planarization process is performed on the dielectric layer 363 and the S/D contacts 216 such that the top surface 363t of the dielectric layer 363 and the top surface 214t of the channel layer 214 may be substantially leveled (or coplanar) with the top surfaces 216t of the S/D contacts 216 and the top surfaces 217t of the barrier liners 217 (if exist), within process variations.

Referring to FIG. 5D and with reference to FIG. 5C, a stack of a regulating layer 213-3 and a gate dielectric layer 212-1 may be formed on the top surface 214t of the channel layer 214, and the top surface 363t of the dielectric layer 363, the top surfaces 216t of the S/D contacts 216, and the top surfaces 217t of the barrier liners 217 (if exist) may remain exposed by the stack of the regulating layer 213-3 and the gate dielectric layer 212-1. The materials and the thicknesses of the regulating layer 213-3 and the gate dielectric layer 212-1 may be similar to the regulating layer 213 and the gate dielectric layer 212, respectively.

Referring to FIG. 5E and with reference to FIG. 5D, a dielectric layer 364 may be formed on the dielectric layer 363 to cover the stack of the regulating layer 213-3 and the gate dielectric layer 212-1. The dielectric layer 364 may be a part of the dielectric layers 36 described in FIG. 1, and thus the material and the forming method of the dielectric layer 364 is not repeated herein. In some embodiments, the dielectric layer 364 is formed on the top surface 363t of the dielectric layer 363, the top surfaces 216t of the S/D contacts 216, and the top surfaces 217t of the barrier liners 217 (if exist). The stack of the regulating layer 213-3 and the gate dielectric layer 212-1 may be buried in the dielectric layer 364. The dielectric layer 364 may be formed with a contact opening accessibly exposing at least a portion of the top surface of the gate dielectric layer 212-1, and then a second gate layer 512 may be formed in the contact opening to be in contact with the top surface of the gate dielectric layer 212-1. In some embodiments, a planarization process is performed on the dielectric layer 364 such that the top surface 364t of the dielectric layer 364 and the top surface 512t of the second gate layer 512 may be substantially leveled (or coplanar), within process variations.

Up to here, the second semiconductor device T2-6 is obtained. The second semiconductor device T2-6 may include a stacked structure including the gate dielectric layer 212, the regulating layer 213, the channel layer 214, the regulating layer 213-3, and the gate dielectric layer 212-1 sequentially stacked from the bottom to the top, and the first gate layer 511 is disposed on the bottom surface of the gate dielectric layer 212 and the second gate layer 512 is disposed on the top surface of the gate dielectric layer 212-1. The S/D contacts 216 may be disposed at two opposing sidewalls of the channel layer 214. The second semiconductor device T2-6 may be formed in the interconnection structure 30 (shown in FIG. 1). For example, the S/D contacts 216 and the first and second gate layers (511 and 512) are further electrically coupled to the conductive patterns 34 and/or the conductive vias 32 of the interconnection structure 30 (shown in FIG. 1). In some embodiments, the second semiconductor device T2-6 is referred to as a double-gated transistor structure. In alternative embodiments, additional features may be added in the semiconductor structure shown in FIG. 5E, and some features in the semiconductor structure shown in FIG. 5E may be modified, replaced, or eliminated without departure of the spirit and scope of the present disclosure.

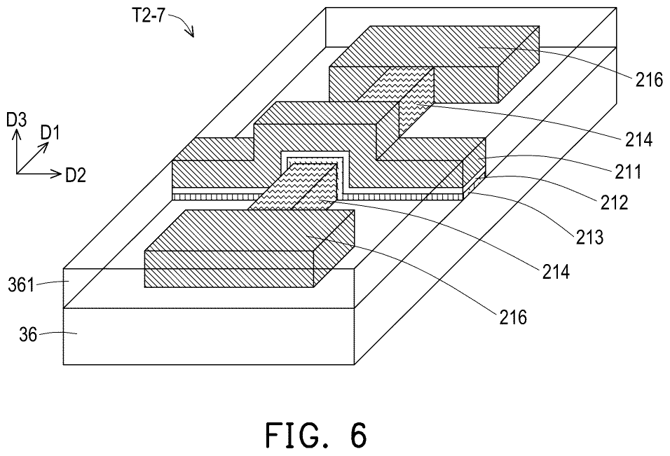

FIG. 6 illustrate a schematic view of a variation of a second semiconductor device in FIG. 1, in accordance with some embodiments. Unless explicitly stated otherwise, the materials and the formation methods of the components in these embodiments are essentially the same as the like components, which are denoted by like reference numerals in the embodiments described in accompanying with FIG. 5E.

Referring to FIG. 6 and with reference to FIG. 5E, the second semiconductor device T2-7 in FIG. 6 is another implementation of the a double-gated transistor structure. The second semiconductor device T2-7 is also referred to as a fin field effect transistor (FinFET) structure. For example, the channel layer 214 forming in a fin form is disposed on the dielectric layer 36 and extends along a first direction D1. The S/D contacts 216 may be disposed at two opposing sides of the channel layer 214 in the first direction D1. The regulating layer 213 may be formed on the dielectric layer 36 and cover the top surface and the opposing sidewalls of the channel layer 214. The regulating layer 213 may extend along a second direction D2 which is substantially perpendicular to the first direction D1. The gate dielectric layer 212 may be conformally disposed on the regulating layer 213. The gate layer 211 may be conformally disposed on the gate dielectric layer 212. The dielectric layer 361 may be stacked on the dielectric layer 36 in a third direction D3 which is substantially perpendicular to the first direction DI and the second direction D2, where the third direction D3 may be the thickness direction of the second semiconductor device T2-7. The dielectric layer 361 may cover the channel layer 214, the S/D contacts 216, the regulating layer 213, the gate dielectric layer 212, and the gate layer 211. In alternative embodiments, additional features may be added in the semiconductor structure shown in FIG. 6, and some features in the semiconductor structure shown in FIG. 6 may be modified, replaced, or eliminated without departure of the spirit and scope of the present disclosure.

It is appreciated that the second semiconductor device T2 of FIG. 1 may be replaced with any one of the second semiconductor devices (e.g., T2-1, T2-2, T2-3, T2-4, T2-5, T2-6, and T2-7) described in the present disclosure. In some embodiments, any combination of the second semiconductor devices (e.g., T2, T2-1, T2-2, T2-3, T2-4, T2-5, T2-6, and/or T2-7) described herein is formed in the interconnect structure 30 of the semiconductor structure 10 shown in FIG. 1.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a semiconductor structure includes a transistor including a gate layer, source/drain contacts, a channel layer including an oxide semiconductor material, a gate dielectric layer connecting the gate layer, and a regulating layer separating the channel layer from the gate dielectric layer. The regulating layer is an oxide layer which prevents oxygen from moving through the regulating layer to the channel layer or the gate dielectric layer.

According to some embodiments, a semiconductor structure includes a transistor embedded in an interconnect structure over a substrate. The transistor includes a stack of a channel layer, a gate dielectric layer, and a regulating layer, the regulating layer interposed between the channel layer and the gate dielectric layer to stop oxygen moving from the channel layer toward the gate dielectric layer or oxygen moving from gate dielectric layer toward the channel layer. The transistor includes a gate layer connecting the gate dielectric layer of the stack and source/drain contacts connecting the stack.

According to some embodiments, a method for forming a semiconductor structure includes forming a transistor. Forming the transistor includes: forming a gate dielectric layer on a gate layer; forming a regulating layer on the gate dielectric layer; forming a channel layer on the regulating layer, where the regulating layer is an oxide layer which prevents oxygen from moving through the regulating layer to the channel layer or the gate dielectric layer; and forming S/D contacts on the channel layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a transistor comprising:
a gate layer;
source/drain (S/D) contacts;
a channel layer comprising an oxide semiconductor material;
a gate dielectric layer connecting the gate layer; and
a regulating layer separating the channel layer from the gate dielectric layer, wherein the regulating layer is an oxide layer which prevents oxygen from moving through the regulating layer to the channel layer or the gate dielectric layer.

2. The semiconductor structure of claim 1, wherein a material of the regulating layer is of the form AxOy, where A represents metallic or non-metallic cations, x represents the number of the metallic or non-metallic cations, O represents oxygen anions, y represents the number of the oxygen anions, and y is greater than x.

3. The semiconductor structure of claim 2, wherein y is 3 or greater than 3.

4. The semiconductor structure of claim 1, wherein the gate dielectric layer is thicker than the regulating layer.

5. The semiconductor structure of claim 1, further comprising:
a semiconductor substrate; and
an interconnect structure disposed over the semiconductor substrate, wherein the transistor is embedded in the interconnect structure.

6. The semiconductor structure of claim 1, wherein:
the gate dielectric layer, the regulating layer, and the channel layer are sequentially stacked upon the gate layer, and
the S/D contacts are disposed on the channel layer.

7. The semiconductor structure of claim 1, wherein the transistor further comprises:
additional regulating layer separating the channel layer from the S/D contacts.

8. The semiconductor structure of claim 1, wherein:
the regulating layer is disposed on the channel layer and a gate oxide layer is disposed on the regulating layer, and
the gate layer and the S/D contacts are disposed on the gate oxide layer, wherein the S/D contacts are disposed at two opposing sidewalls of the gate layer.

9. The semiconductor structure of claim 1, wherein:
the gate dielectric layer, the regulating layer, and the channel layer are sequentially stacked upon the gate layer, and
the S/D contacts are disposed at two opposing sides of the channel layer.

10. The semiconductor structure of claim 1, wherein the transistor further comprises:
hydrogen barriers respectively surrounding the S/D contacts to prevent hydrogen from diffusion through the hydrogen barriers to the channel layer.

11. A semiconductor structure, comprising:
a transistor embedded in an interconnect structure over a substrate, the transistor comprising:
a stack of a channel layer, a gate dielectric layer, and a regulating layer, the regulating layer interposed between the channel layer and the gate dielectric layer to stop oxygen moving from the channel layer toward the gate dielectric layer or oxygen moving from gate dielectric layer toward the channel layer;
a gate layer connecting the gate dielectric layer of the stack; and
source/drain (S/D) contacts connecting the stack.

12. The semiconductor structure of claim 11, wherein an average oxidation state of the regulating layer is at least +3.

13. The semiconductor structure of claim 11, wherein the regulating layer provides oxygen vacancies which are filled by oxygen moving from the channel layer or the gate dielectric layer.

14. The semiconductor structure of claim 11, wherein sidewalls of the channel layer, the gate dielectric layer, and the regulating layer are substantially coplanar.

15. The semiconductor structure of claim 11, wherein the transistor further comprises:
barrier liners respectively surrounding the S/D contacts and comprising a hydrogen barrier material.

16. The semiconductor structure of claim 11, wherein the stack of the transistor further comprises:
additional regulating layer separating the channel layer from the S/D contacts to stop oxygen moving from the channel layer toward the S/D contacts.

17. A manufacturing method of a semiconductor structure, comprising:
forming a transistor comprising:
forming a gate dielectric layer on a gate layer;
forming a regulating layer on the gate dielectric layer;
forming a channel layer on the regulating layer, wherein the regulating layer is an oxide layer which prevents oxygen from moving through the regulating layer to the channel layer or the gate dielectric layer; and
forming S/D contacts on the channel layer.

18. The method of claim 17, wherein a material of the regulating layer is of the form AxOy, where A represents metallic or non-metallic cations, x represents the number of the metallic or non-metallic cations, O represents oxygen anions, y represents the number of the oxygen anions, and y is greater than x.

19. The method of claim 17, wherein forming the regulating layer on the gate dielectric layer comprises:
forming the regulating layer thinner than the gate dielectric layer.

20. The method of claim 17, wherein forming the transistor comprises:
performing a back-end-of-line process to form the transistor in an interconnect structure over a semiconductor substrate.
